(19) United States
(12) Patent Application Publication
(10) Pub. No.: US 2024/0260388 A1
(43) Pub. Date: Aug. 1, 2024

(54) MOTHER SUBSTRATE FOR DISPLAY DEVICE, DISPLAY DEVICE AND MANUFACTURING METHOD OF DISPLAY DEVICE

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 18/395,789

(22) Filed: Dec. 26, 2023

(30) Foreign Application Priority Data
Jan. 31, 2023 (JP) 2023-012902

(51) Int. Cl. H10K 59/80; H10K 71/00; H10K 71/20; H10K 71/60

(52) U.S. Cl. CPC H10K 59/80515; H10K 59/80521; H10K 59/871; H10K 71/20; H10K 71/60; H10K 71/621

(57) ABSTRACT

According to one embodiment, a mother substrate for a display device includes a plurality of panel portions each of which includes a display area in which display elements are provided, a margin area around the panel portions, and a first partition in the margin area. Each of the display elements includes a lower electrode, an upper electrode and an organic layer. Further, the first partition includes a first lower portion formed of an organic insulating material, and a first upper portion including an end portion which protrudes from a side surface of the lower portion.

### CROSS-REFERENCE TO RELATED APPLICATIONS

This application is based upon and claims the benefit of priority from Japanese Patent Application No. 2023-012902, filed Jan. 31, 2023, the entire contents of which are incorporated herein by reference.

### FIELD

Embodiments described herein relate generally to a mother substrate for a display device, a display device and a manufacturing method of a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

When display devices are manufactured, a plurality of panel portions each including a display area in which a large number of display elements are provided are formed in a large mother substrate. Further, a display panel which is a main element of each display device is manufactured by cutting each panel portion out. In this manufacturing process, a technique for improving the yield is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view of a display panel along the III-III line of FIG. 2.

FIG. 4 is a schematic plan view of a mother substrate according to the first embodiment.

FIG. 5 is a schematic plan view of part of the mother substrate according to the first embodiment.

FIG. 6 is a schematic cross-sectional view of a margin area along the VI-VI line of FIG. 5.

FIG. 7 is a flowchart showing an example of the manufacturing method of the mother substrate and the display device according to the first embodiment.

FIG. 8A is a schematic cross-sectional view of a display area in the mother substrate during the manufacturing process.

FIG. 8B is a schematic cross-sectional view of a margin area in the mother substrate during the manufacturing process.

FIG. 9A is a schematic cross-sectional view of the display area and shows a process following

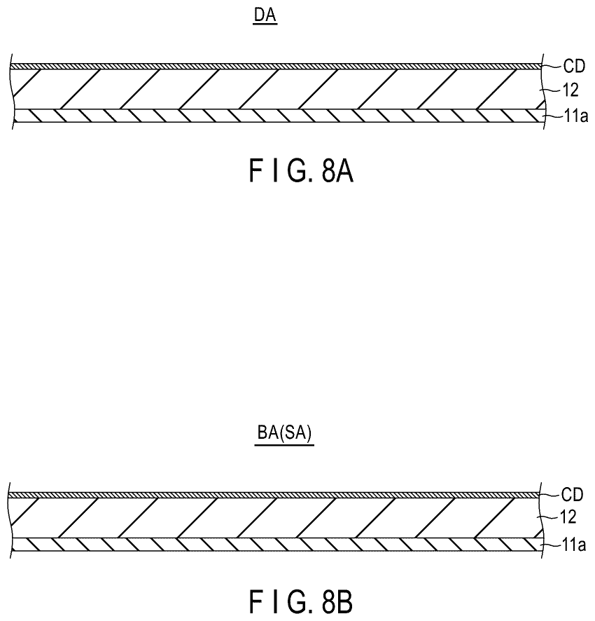

FIG. 8A.

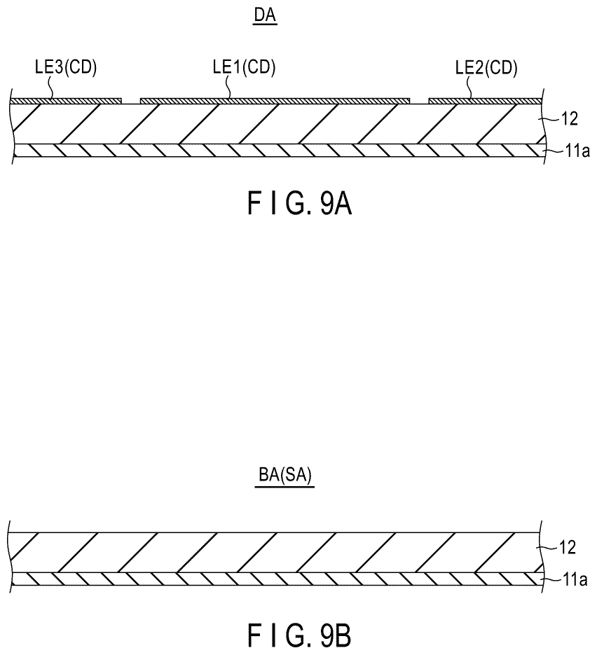

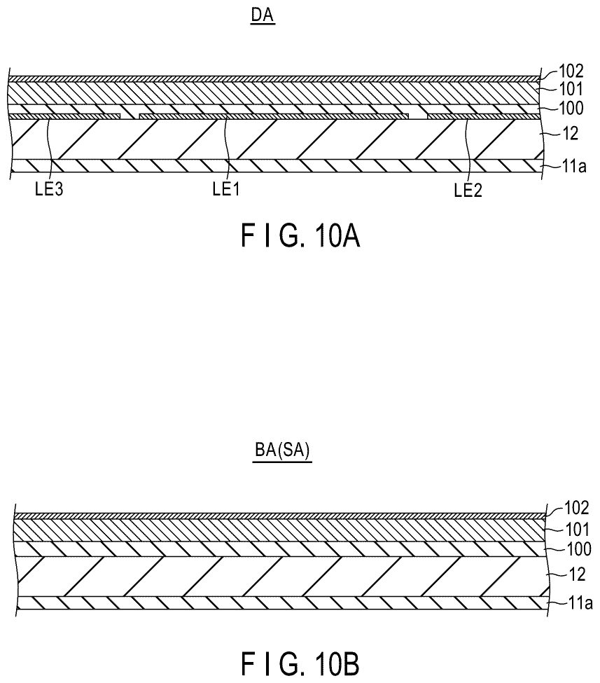

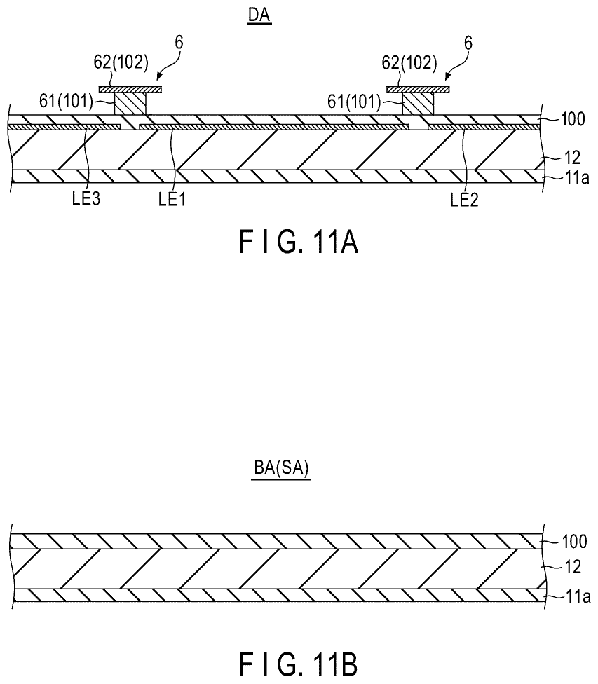

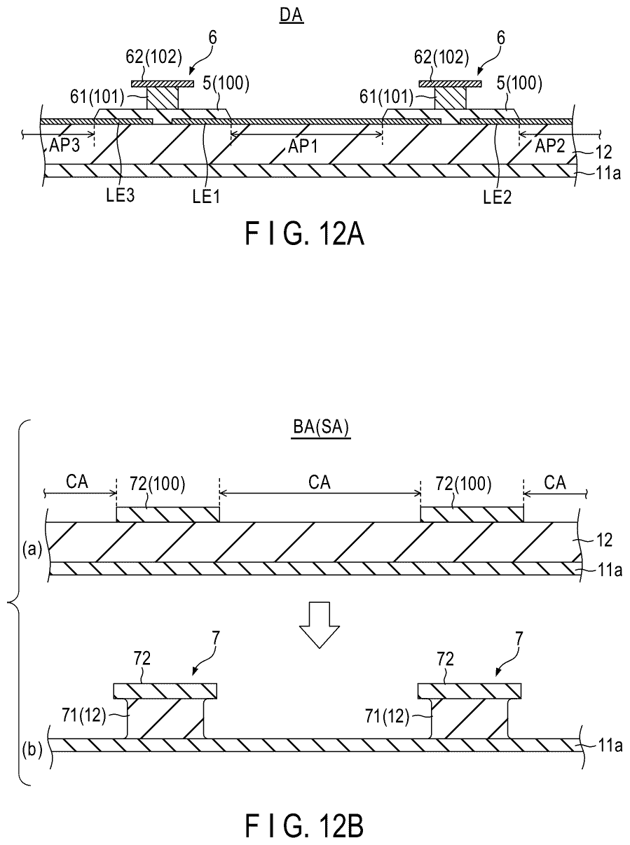

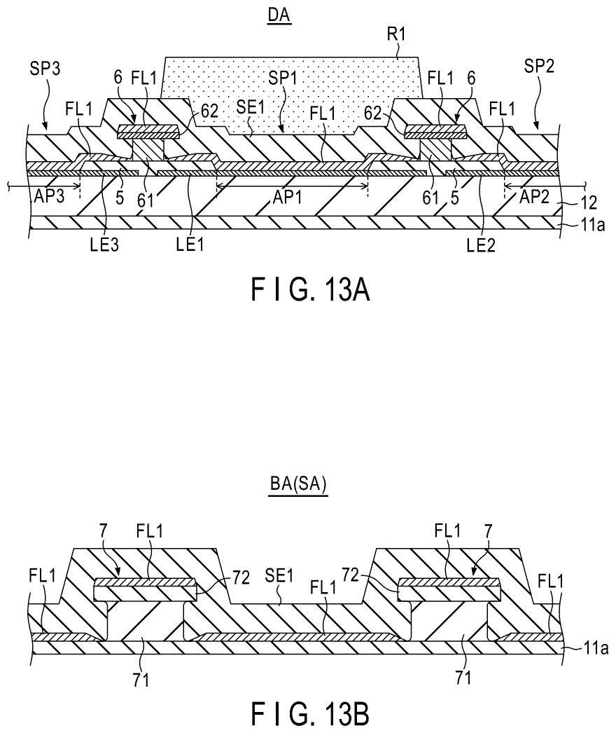

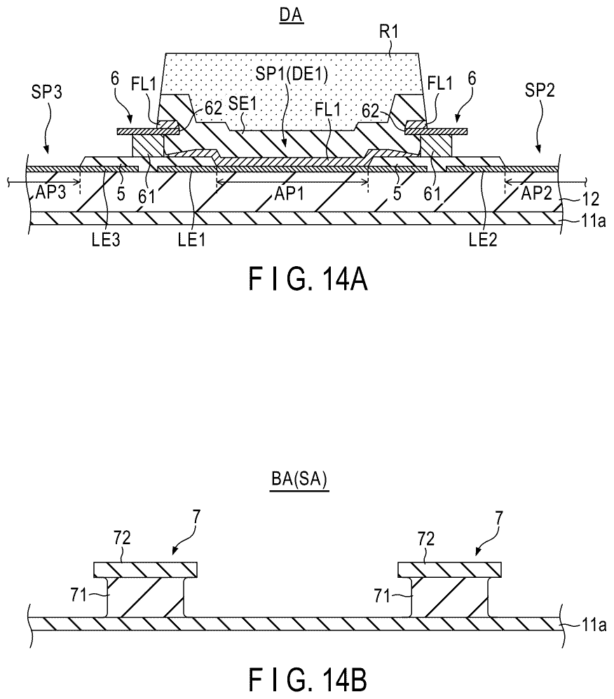

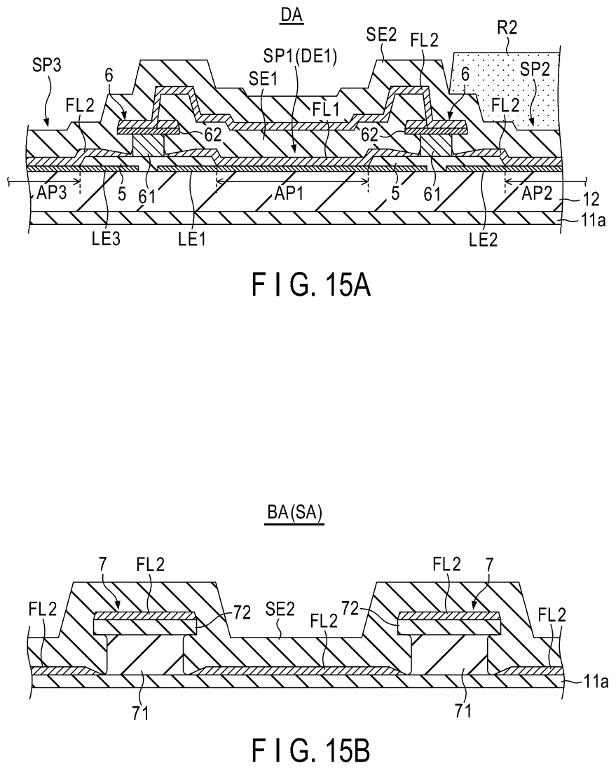

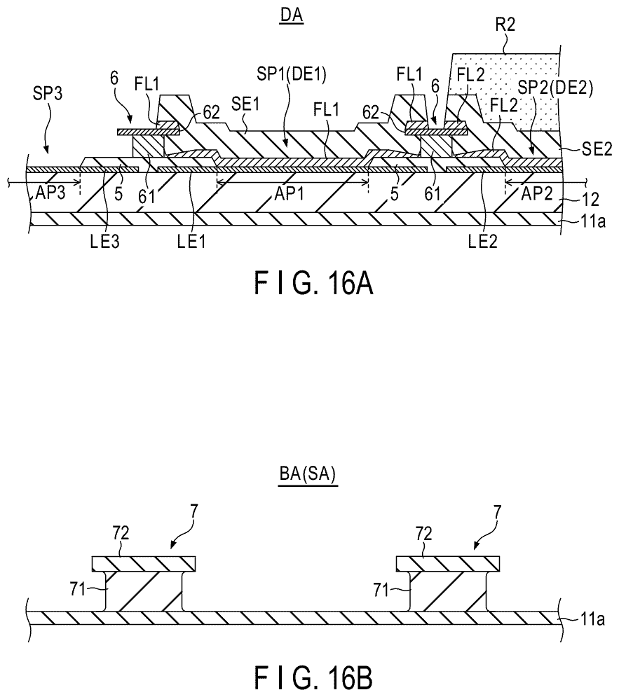

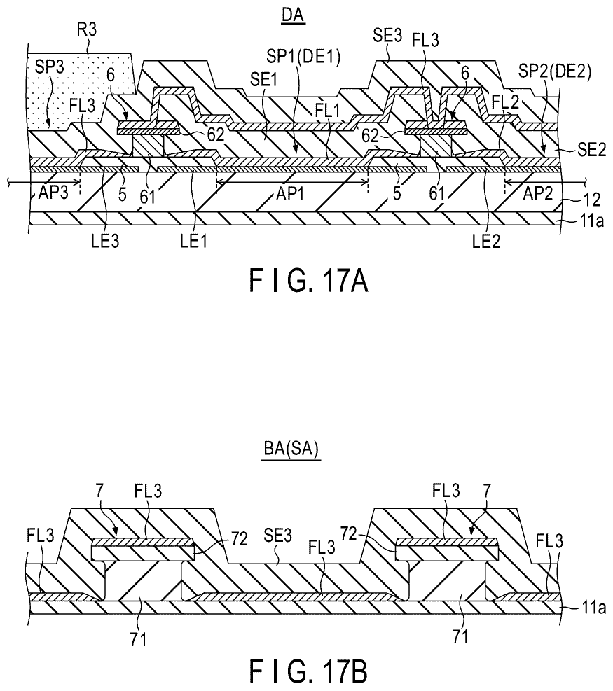

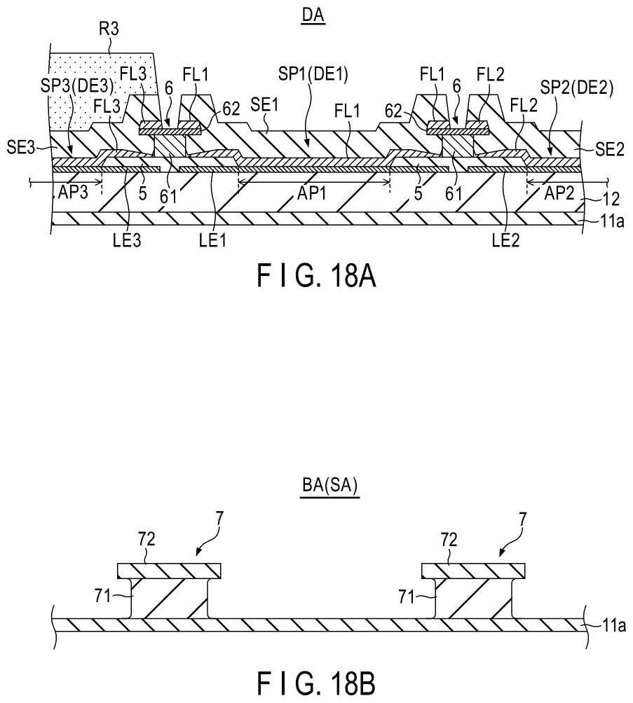

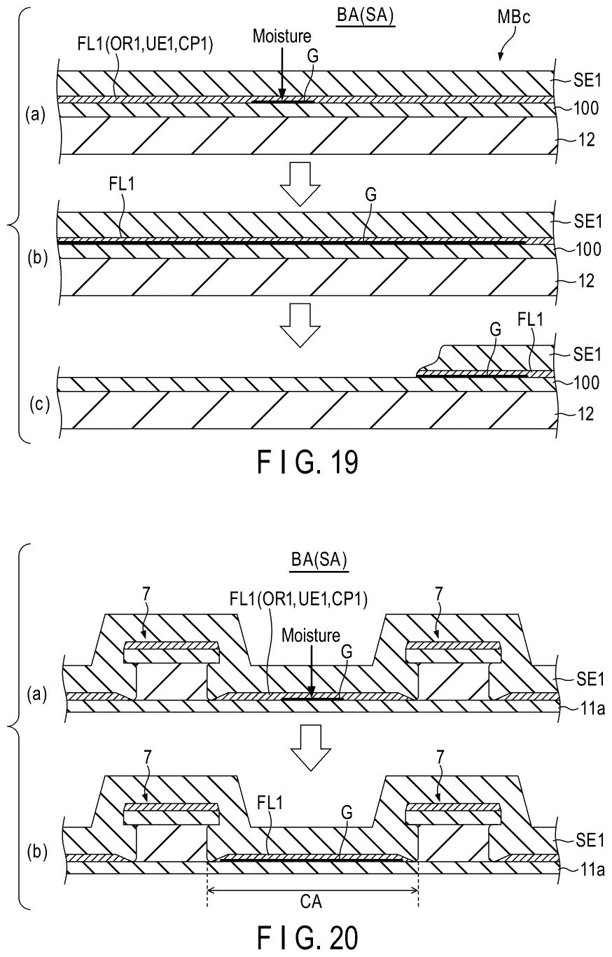

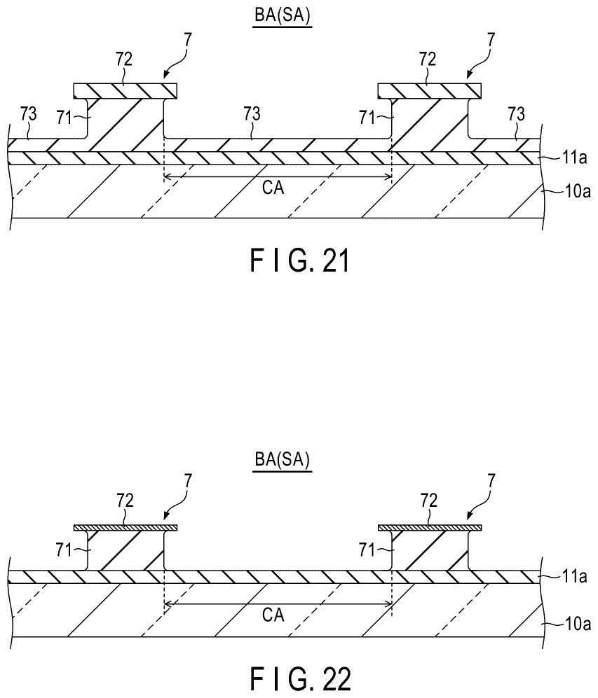

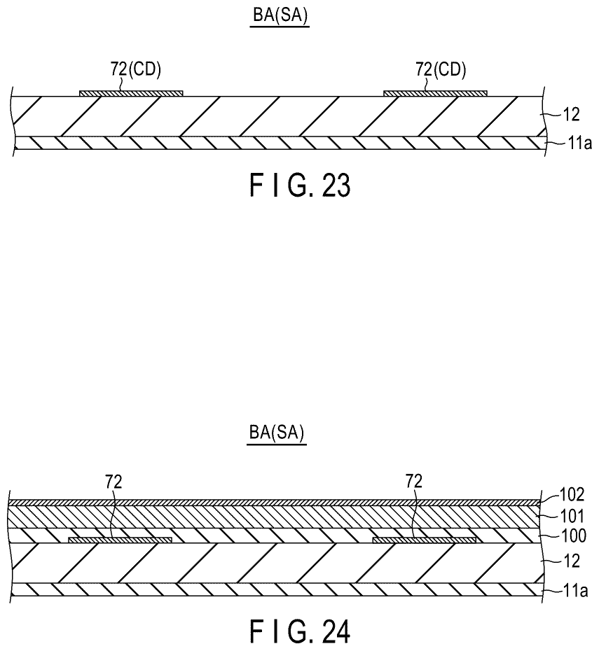

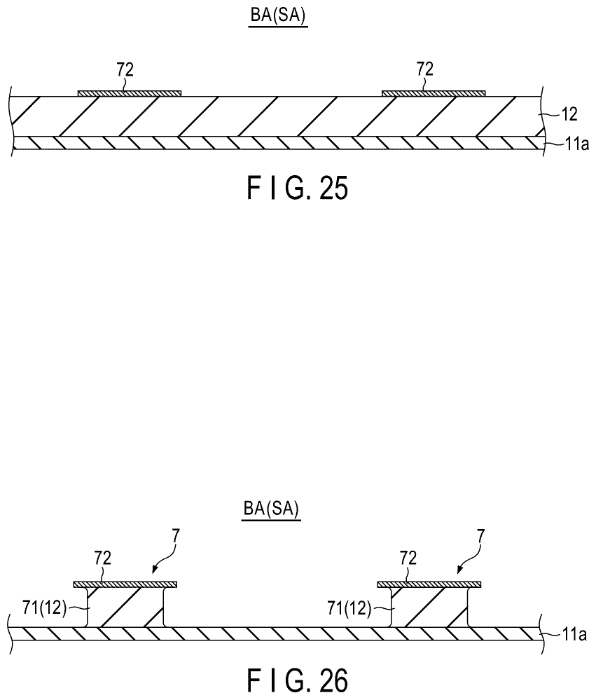

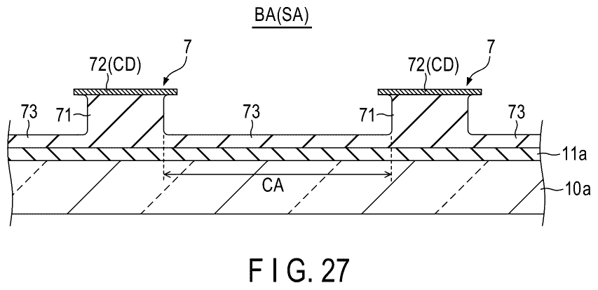

FIG. 9B is a schematic cross-sectional view of the margin area and shows a process following FIG. 8B.

FIG. 10A is a schematic cross-sectional view of the display area and shows a process following FIG. 9A.

FIG. 10B is a schematic cross-sectional view of the margin area and shows a process following FIG. 9B.

FIG. 11A is a schematic cross-sectional view of the display area and shows a process following FIG. 10A.

FIG. 11B is a schematic cross-sectional view of the margin area and shows a process following FIG. 10B.

FIG. 12A is a schematic cross-sectional view of the display area and shows a process following FIG. 11A.

FIG. 12B is a schematic cross-sectional view of the margin area and shows a process following FIG. 11B.

FIG. 13A is a schematic cross-sectional view of the display area and shows a process following FIG. 12A.

FIG. 13B is a schematic cross-sectional view of the margin area and shows a process following FIG. 12B.

FIG. 14A is a schematic cross-sectional view of the display area and shows a process following FIG. 13A.

FIG. 14B is a schematic cross-sectional view of the margin area and shows a process following FIG. 13B.

FIG. 15A is a schematic cross-sectional view of the display area and shows a process following FIG. 14A.

FIG. 15B is a schematic cross-sectional view of the margin area and shows a process following FIG. 14B.

FIG. 16A is a schematic cross-sectional view of the display area and shows a process following FIG. 15A.

FIG. 16B is a schematic cross-sectional view of the margin area and shows a process following FIG. 15B.

FIG. 17A is a schematic cross-sectional view of the display area and shows a process following FIG. 16A.

FIG. 17B is a schematic cross-sectional view of the margin area and shows a process following FIG. 16B.

FIG. 18A is a schematic cross-sectional view of the display area and shows a process following FIG. 17A.

FIG. 18B is a schematic cross-sectional view of the margin area and shows a process following FIG. 17B.

FIG. 19 is a schematic cross-sectional view of the margin area of a mother substrate according to a comparative example.

FIG. 20 is a schematic cross-sectional view of the margin area of the mother substrate according to the first embodiment.

FIG. 21 is a schematic cross-sectional view of a margin area according to a second embodiment.

FIG. 22 is a schematic cross-sectional view of a margin area according to a third embodiment.

FIG. 23 is a schematic cross-sectional view showing a process for forming a partition in the margin area according to the third embodiment.

FIG. 24 is a schematic cross-sectional view of the margin area and shows a process following FIG. 23.

FIG. 25 is a schematic cross-sectional view of the margin area and shows a process following FIG. 24.

FIG. 26 is a schematic cross-sectional view of the margin area and shows a process following FIG. 25.

FIG. 27 is a schematic cross-sectional view of a margin area according to a fourth embodiment.

### DETAILED DESCRIPTION

In general, according to one embodiment, a mother substrate for a display device comprises a plurality of panel portions each of which includes a display area in which a plurality of display elements are provided, a margin area around the panel portions, and a first partition provided in the margin area. Each of the display elements includes a lower electrode, an upper electrode which faces the lower electrode, and an organic layer which is provided between the lower electrode and the upper electrode and emits light based on a potential difference between the lower electrode and the upper electrode. Further, the first partition includes a first lower portion formed of an organic insulating material, and a first upper portion comprising an end portion which protrudes from a side surface of the lower portion.

According to another aspect of the embodiment, a display device comprises a display area in which a plurality of display elements are provided, a surrounding area around the display area, and a first partition provided in the surrounding area. Each of the display elements includes a lower electrode, an upper electrode which faces the lower electrode, and an organic layer which is provided between the lower electrode and the upper electrode and emits light based on a potential difference between the lower electrode and the upper electrode. Further, the first partition includes a first lower portion formed of an organic insulating material and a first upper portion comprising an end portion which protrudes from a side surface of the first lower portion.

According to yet another aspect of the embodiment, a manufacturing method of a display device includes preparing a substrate including a plurality of panel portions each of which includes a display area, and a margin area around the panel portions, forming an organic insulating layer formed of an organic insulating material in the display area and the margin area, forming a conductive layer formed of a conductive material which covers the organic insulating layer in the display area and the margin area, forming a lower electrode of a display element by patterning the conductive layer in the display area, forming an inorganic insulating layer formed of an inorganic insulating material which covers the lower electrode in the display area and the margin area, forming a rib comprising a pixel aperture overlapping the lower electrode by patterning the inorganic insulating layer in the display area, and forming a first partition including a first lower portion and a first upper portion comprising an end portion which protrudes from a side surface of the first lower portion in the margin area. Further, the forming the first partition includes forming the first upper portion by patterning the conductive layer or the inorganic insulating layer in the margin area, and forming the first lower portion by removing a portion of the organic insulating layer exposed from the first upper portion and reducing a width of the organic insulating layer which remains under the first upper portion in the margin area.

One of the objects of the present invention is to provide a mother substrate for a display device, a display device and a manufacturing method of a display device such that the yield can be improved.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. The third direction Z is a normal direction relative to a plane including the first direction X and the second direction Y. When various elements are viewed parallel to the third direction Z, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

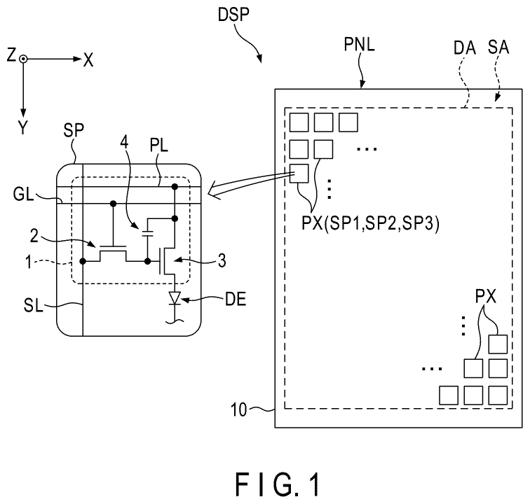

FIG. 1 is a diagram showing a configuration example of a display device DSP according to a first embodiment. The display device DSP comprises a display panel PNL including an insulating substrate 10. The display panel PNL comprises a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes a blue subpixel SP1, a green subpixel SP2 and a red subpixel SP3. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

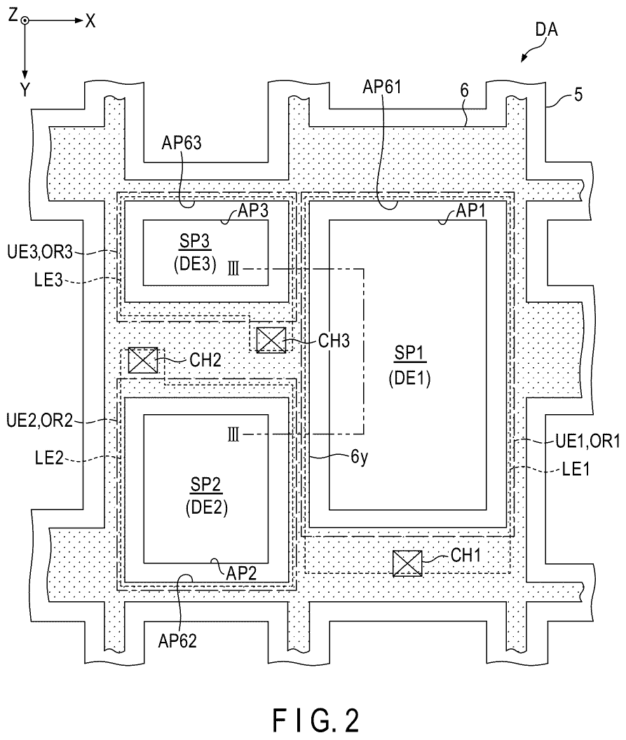

FIG. 2 is a schematic plan view showing an example of the layout of subpixels SP1, SP2 and SP3. In the example of FIG. 2, each of subpixels SP2 and SP3 is adjacent to subpixel SP1 in the first direction X. Further, subpixels SP2 and SP3 are arranged in the second direction Y.

When subpixels SP1, SP2 and SP3 are provided in line with this layout, in the display area DA, a column in which subpixels SP2 and SP3 are alternately provided in the second direction Y and a column in which a plurality of subpixels SP1 are repeatedly provided in the second direction Y are formed. These columns are alternately arranged in the first direction X. It should be noted that the layout of subpixels SP1, SP2 and SP3 is not limited to the example of FIG. 2.

A rib 5 is provided in the display area DA. The rib 5 comprises pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 surrounds each of these display elements DE1, DE2 and DE3.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

The partition 6 (second partition) is provided on the rib 5. The partition 6 overlaps the rib 5 as a whole and has the same planar shape as the rib 5. In other words, the partition 6 comprises apertures AP61, AP62 and AP63 in subpixels SP1, SP2 and SP3, respectively. From another viewpoint, the rib 5 and the partition 6 are provided between the display elements DE1, DE2 and DE3, and have grating shapes as seen in plan view.

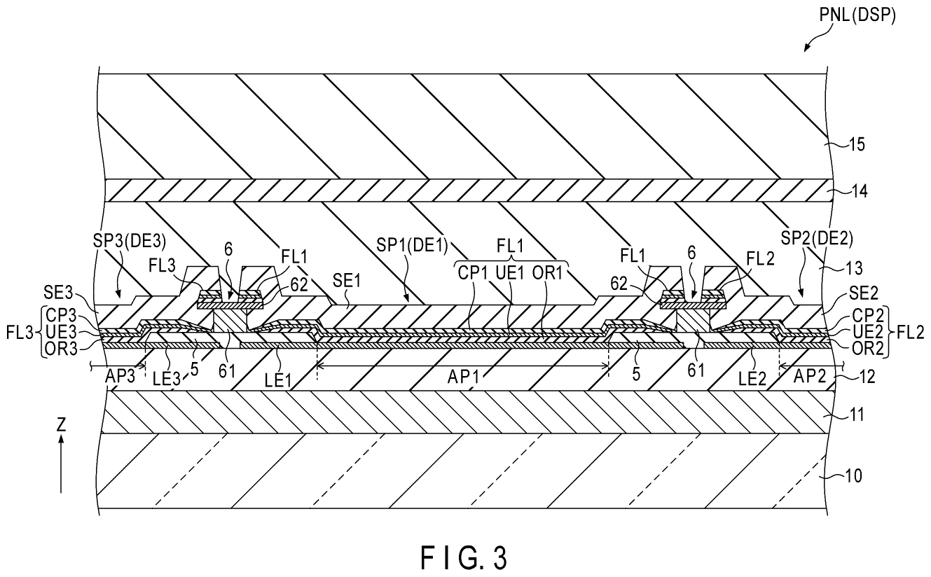

FIG. 3 is a schematic cross-sectional view of the display panel PNL along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1.

The circuit layer 11 is covered with an organic insulating layer 12. The organic insulating layer 12 functions as a planarization film which planarizes the irregularities formed by the circuit layer 11. Although not shown in the section of FIG. 3, the contact holes CH1, CH2 and CH3 described above are provided in the organic insulating layer 12.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5.

The partition 6 includes a conductive lower portion (second lower portion) 61 provided on the rib 5 and an upper portion (second upper portion) 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portion 61 of the partition 6.

In the example of FIG. 3, a cap layer CP1 is provided on the upper electrode UE1. A cap layer CP2 is provided on the upper electrode UE2. A cap layer CP3 is provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located under the partition 6 (in other words, the portion which constitutes the display element DE1). Similarly, the stacked film FL2 is partly located on the upper portion 62. This portion is spaced apart from, of the stacked film FL2, the portion located under the partition 6 (in other words, the portion which constitutes the display element DE2). Further, the stacked film FL3 is partly located on the upper portion 62. This portion is spaced apart from, of the stacked film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the stacked film FL1 and the partition 6 around subpixel SP1. The sealing layer SE2 continuously covers the stacked film FL2 and the partition 6 around subpixel SP2. The sealing layer SE3 continuously covers the stacked film FL3 and the partition 6 around subpixel SP3.

In the example of FIG. 3, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The organic insulating layer 12 is formed of an organic insulating material such as polyimide. Each of the rib 5 and the sealing layers 14, SE1, SE2 and SE3 is formed of an inorganic insulating material such as silicon nitride (SiNx), silicon oxide (SiOx), silicon oxynitride (SiON) or aluminum oxide (Al₂O₃). For example, the rib 5 is formed of silicon oxynitride, and each of the sealing layers 14, SE1, SE2 and SE3 is formed of silicon nitride. Each of the resin layers 13 and 15 is formed of, for example, a resinous material (organic insulating material) such as epoxy resin or acrylic resin.

Each of the lower electrodes LE1, LE2 and LE3 comprises a reflective layer formed of, for example, silver (Ag), and a pair of conductive oxide layers covering the upper and lower surfaces of the reflective layer. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 comprises, for example, a multilayer structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers.

Each of the cap layers CP1, CP2 and CP3 comprises, for example, a multilayer structure in which a plurality of transparent thin films are stacked. The thin films may include a thin film formed of an inorganic material and a thin film formed of an organic material. These thin films have refractive indices different from each other. The materials of these thin films are different from the materials of the upper electrodes UE1, UE2 and UE3 and are also different from the materials of the sealing layers SE1, SE2 and SE3. It should be noted that at least one of the cap layers CP1, CP2 and CP3 may be omitted.

The lower portion 61 of the partition 6 is formed of, for example, aluminum. The lower portion 61 may be formed of an aluminum alloy such as an aluminum-neodymium alloy (AlNd), an aluminum-yttrium alloy (AlY) or an aluminum-silicon alloy (AlSi), or may comprise a multilayer structure consisting of an aluminum layer and an aluminum alloy layer. Further, the lower portion 61 may comprise a bottom layer formed of a metal material different from aluminum and an aluminum alloy under the aluminum layer or the aluminum alloy layer. For the metal material forming the bottom layer, for example, molybdenum (Mo), titanium nitride (TiN), a molybdenum-tungsten alloy (MoW) or a molybdenum-niobium alloy (MoNb) may be used.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may comprise a single-layer structure of a metal material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

When the display device DSP is manufactured, a large mother substrate in which a plurality of areas (panel portions) each corresponding to the display panel PNL are formed is prepared. A configuration which could be applied to this mother substrate is explained below.

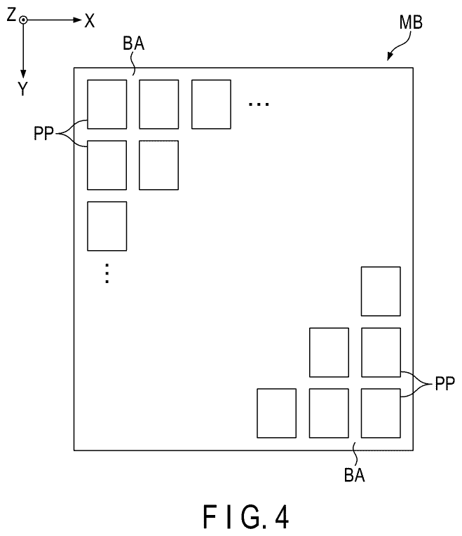

FIG. 4 is a schematic plan view of a mother substrate MB (a mother substrate for a display device) according to the embodiment. The mother substrate MB is, for example, rectangular as shown in the figure. However, the mother substrate MB may have another shape such as a circle. The mother substrate MB comprises a plurality of panel portions PP provided in matrix, and a margin area BA around these panel portions PP.

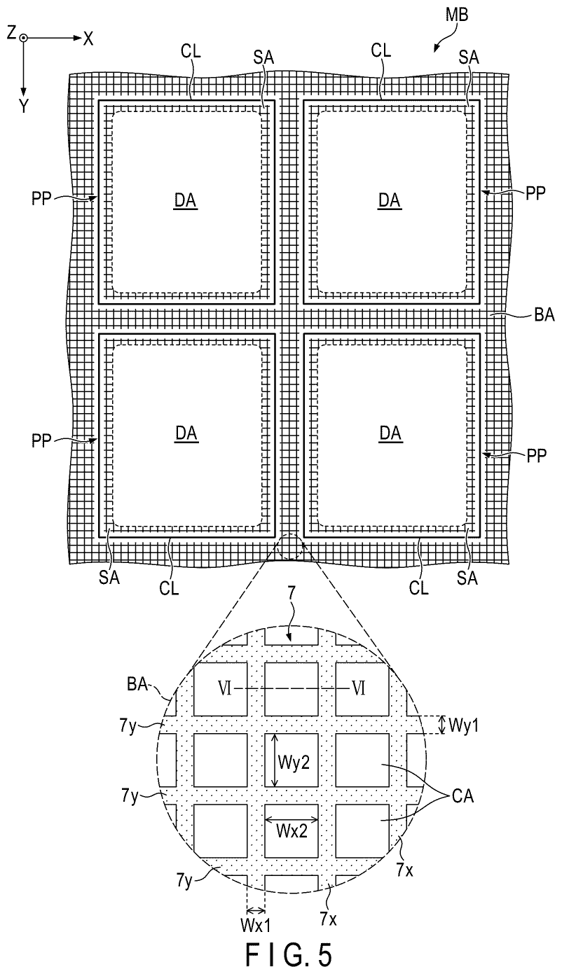

FIG. 5 is a schematic plan view of part of the mother substrate MB. The outer shape of each panel portion PP corresponds to a cut line CL for cutting the panel portion PP from the mother substrate MB. Each panel portion PP comprises the display area DA and surrounding area SA described above.

As shown in the enlarged view of FIG. 5, a partition (first partition) 7 is provided in the margin area BA. The partition 7 comprises a plurality of first linear portions 7x provided parallel to each other, and a plurality of second linear portions 7y provided parallel to each other.

The first linear portions 7x extend in the second direction Y and are arranged in the first direction X. The second linear portions 7y extend in the first direction X and are arranged in the second direction Y. In the example of FIG. 5, the first linear portions 7x and the second linear portions 7y intersect each other. In this configuration, the partition 7 has a grating shape as a whole.

From another viewpoint, the partition 7 forms a plurality of closed areas CA. Each of the closed areas CA is a square or rectangular area surrounded by adjacent two first linear portions 7x and adjacent two second linear portions 7y.

Each of the first linear portions 7x has width Wx1 in the first direction X. Each of the second linear portions 7y has width Wy1 in the second direction Y. Each of the closed areas CA has width Wx2 in the first direction X and has width Wy2 in the second direction Y. Width Wx2 corresponds to the layout interval of the first linear portions 7x. Width Wy2 corresponds to the layout interval of the second linear portions 7y.

For example, width Wx2 is greater than the width of each of subpixels SP1, SP2 and SP3 in the first direction X. Width Wy2 is greater than the width of each of subpixels SP1, SP2 and SP3 in the second direction Y. In the example of FIG. 5, widths Wx2 and Wy2 are greater than widths Wx1 and Wy1, respectively (Wx2>Wx1, Wy2>Wy1). As explained in detail later, at least one of widths Wx2 and Wy2 should be preferably less than or equal to 200 μm (Wx2, Wy2≤200 μm).

The pattern of the grating shape of the mother substrate MB in FIG. 5 shows the area in which the partition 7 is provided. In other words, in the example of FIG. 5, the partition 7 is provided in the surrounding areas SA in addition to the margin area BA. The partition 7 is not provided in the display areas DA. The partition 7 provided in the surrounding areas SA remains in the panel portions PP (display panels PNL) even after the panel portions PP are cut out along the cut lines CL.

To efficiently cut the panel portions PP out, preferably, the partition 7 should not be provided in the cut lines CL. In this case, the partition 7 provided in the surrounding areas SA and the partition 7 provided in the margin area BA are divided from each other in the boundaries between the surrounding areas SA and the margin area BA.

It should be noted that the partition 7 is not necessarily provided in the entire surrounding areas SA or margin area BA. The partition 7 may be provided in part of the surrounding areas SA and margin area BA, and the partition 7 may not be provided in the remaining part.

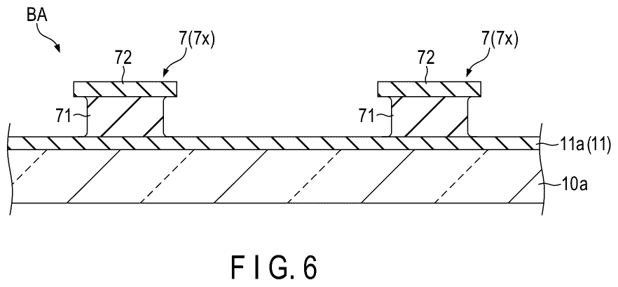

FIG. 6 is a schematic cross-sectional view of the margin area BA along the VI-VI line of FIG. 5. The mother substrate MB comprises an insulating substrate 10a. When the panel portions PP are cut out from the mother substrate MB, the substrate 10a is cut along the cut lines CL. The substrate 10a of each panel portion PP which has been cut out corresponds to the substrate 10 shown in FIG. 3, etc.

The mother substrate MB comprises an underlayer 11a provided above the substrate 10a in the margin area BA. The underlayer 11a is, for example, part of the circuit layer 11 shown in FIG. 3, and is provided in the display area DA as well. The underlayer 11a is formed of an inorganic material such as silicon nitride, silicon oxide or silicon oxynitride.

The partition 7 includes a lower portion (first partition) 71 provided on the underlayer 11a and an upper portion (first upper portion) 72 provided on the lower portion 71. The upper portion 72 has a width which is greater than that of the lower portion 71. By this configuration, the both end portions of the upper portion 72 protrude relative to the side surfaces of the lower portion 71. Thus, the partition 7 has an overhang shape in the same manner as the partition 6 shown in FIG. 3.

In the embodiment, the lower portion 71 is formed of the same organic insulating material as the organic insulating layer 12. The upper portion 72 is formed of the same inorganic insulating material as the rib 5.

It should be noted that the structure of the margin area BA is not limited to the example of FIG. 6. Another insulating layer or conductive layer may be interposed between the substrate 10a and the underlayer 11a. The underlayer 11a and the partition 7 may be covered with another insulating layer or conductive layer.

Now, this specification explains the manufacturing method of the mother substrate MB and the display device DSP.

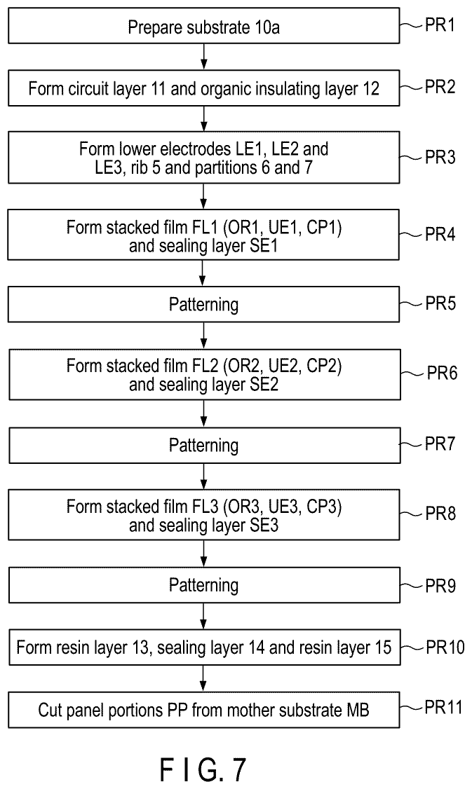

FIG. 7 is a flowchart showing an example of the manufacturing method of the mother substrate MB and the display device DSP. Each of FIG. 8A to FIG. 18A is a schematic cross-sectional view of the display area DA in the mother substrate MB during the manufacturing process. Each of FIG. 8B to FIG. 18B is a schematic cross-sectional view of the margin area BA in the mother substrate MB during the manufacturing process. The same manufacturing process as FIG. 8B to FIG. 18B can be applied to the surrounding area SA. It should be noted that the elements located under the underlayer 11a are omitted in FIG. 8A to FIG. 18A and FIG. 8B to FIG. 18B.

To manufacture the display device DSP, first, a large substrate 10a including areas corresponding to a plurality of panel portions PP and the margin area BA is prepared (process PR1). Subsequently, the circuit layer 11 and the organic insulating layer 12 are formed on the substrate 10a (process PR2).

After process PR2, the lower electrodes LE1, LE2 and LE3, the rib 5, the partition 6 and the partition 7 are formed (process PR3). The flow of process PR3 in the embodiment is as shown in FIG. 8A to FIG. 12A and FIG. 8B to FIG. 12B.

Specifically, first, as shown in FIG. 8A and FIG. 8B, a conductive layer CD which should be processed into the lower electrodes LE1, LE2 and LE3 is formed for the entire mother substrate MB including the display area DA, the margin area BA and the surrounding area SA. The conductive layer CD covers the organic insulating layer 12. When each of the lower electrodes LE1, LE2 and LE3 comprises a pair of conductive oxide layers and a reflective layer between the conductive oxide layers as described above, the conductive layer CD includes three layers which correspond to these conductive oxide layers and reflective layer, respectively.

Subsequently, as shown in FIG. 9A and FIG. 9B, the conductive layer CD is patterned. By this process, the lower electrodes LE1, LE2 and LE3 are formed in the display area DA. In the margin area BA and the surrounding area SA, the conductive layer CD is removed as a whole.

After patterning the conductive layer CD, as shown in FIG. 10A and FIG. 10B, an inorganic insulating layer 100 which should be processed into the rib 5 is formed in the entire mother substrate MB. Further, a first layer 101 which should be processed into the lower portion 61 is formed on the inorganic insulating layer 100. A second layer 102 which should be processed into the upper portion 62 is formed on the first layer 101.

Subsequently, as shown in FIG. 11A and FIG. 11B, the first layer 101 and the second layer 102 are patterned. This patterning includes etching for processing the second layer 102 into the shape of the upper portion 62 and etching for processing the first layer 101 into the shape of the lower portion 61. By these etching processes, the partition 6 including the lower portion 61 and the upper portion 62 is formed in the display area DA. In the margin area BA and the surrounding area SA, the first layer 101 and the second layer 102 are removed as a whole. A conductive layer for connecting the partition 6 to the power supply line of common voltage may be formed in the surrounding area SA by using the first layer 101 and the second layer 102.

After the formation of the partition 6, as shown in FIG. 12A, the inorganic insulating layer 100 is patterned, and the pixel apertures AP1, AP2 and AP3 which overlap the lower electrodes LE1, LE2 and LE3, respectively, are formed. By this process, the rib 5 is formed in the display area DA.

In this patterning, as shown in FIG. 12B(a), of the inorganic insulating layer 100, a portion corresponding to each closed area CA (see FIG. 5) is removed. By this process, the upper portion 72 formed of an inorganic insulating material is formed in the margin area BA and the surrounding area SA. Subsequently, ashing is performed for the organic insulating layer 12. In this ashing, as shown in FIG. 12B(b), the portion of the organic insulating layer 12 exposed from the upper portion 72 is removed, and the width of the organic insulating layer 12 which remains under the upper portion 72 is reduced. By this process, the lower portion 71 formed of an organic insulating material is prepared.

After the above process PR3, a process for forming the display elements DE1, DE2 and DE3 is performed. In the embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 13A and FIG. 13B, the stacked film FL1 and the sealing layer SE1 are formed in the entire mother substrate MB (process PR4). The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 are formed by vapor deposition. The sealing layer SE1 is formed by chemical vapor deposition (CVD).

The stacked film FL1 is divided into a plurality of portions by the partitions 6 and 7 having overhang shapes. As shown in FIG. 13A, the stacked film FL1 in the display area DA covers the lower electrodes LE1, LE2 and LE3 exposed from the pixel apertures AP1, AP2 and AP3, the rib 5 and the partition 6. As shown in FIG. 13B, the stacked film FL1 in the margin area BA and the surrounding area SA covers underlayer 11a and the partition 7. The sealing layer SE1 continuously covers the divided portions of the stacked film FL1 and the partitions 6 and 7.

After process PR4, the stacked film FL1 and the sealing layer SE1 are patterned (process PR5). In this patterning, as shown in FIG. 13A, a resist R1 is provided on the sealing layer SE1. The resist R1 covers subpixel SP1 and part of the partition 6 around the subpixel. The resist R1 is not provided in the margin area BA or the surrounding area SA.

Subsequently, as shown in FIG. 14A, the portions of the stacked film FL1 and the sealing layer SE1 exposed from the resist R1 are removed by etching using the resist R1 as a mask. By this process, the display element DE1 is formed in subpixel SP1. For example, this etching includes wet etching and dry etching processes which are performed in order for the sealing layer SE1, the cap layer CP1, the upper electrode UE1 and the organic layer OR1.

The margin area BA and the surrounding area SA are also exposed to this etching. Thus, as shown in FIG. 14B, the stacked film FL1 and the sealing layer SE1 provided in the margin area BA and the surrounding area SA are removed. After this etching, the resist R1 is removed.

The display element DE2 is formed by a procedure similar to that of the display element DE1. Specifically, to form the display element DE2, first, as shown in FIG. 15A and FIG. 15B, the stacked film FL2 and the sealing layer SE2 are formed in the entire mother substrate MB (process PR6). The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2. The organic layer OR2, the upper electrode UE2 and the cap layer CP2 are formed by vapor deposition. The sealing layer SE2 is formed by CVD.

The stacked film FL2 is divided into a plurality of portions by the partitions 6 and 7 having overhang shapes. The sealing layer SE2 continuously covers the divided portions of the stacked film FL2 and the partitions 6 and 7.

After process PR6, the stacked film FL2 and the sealing layer SE2 are patterned (process PR7). In this patterning, as shown in FIG. 15A, a resist R2 is provided on the sealing layer SE2. The resist R2 covers subpixel SP2 and part of the partition 6 around the subpixel. The resist R2 is not provided in the margin area BA or the surrounding area SA.

Subsequently, as shown in FIG. 16A, the portions of the stacked film FL2 and the sealing layer SE2 exposed from the resist R2 are removed by etching using the resist R2 as a mask. By this process, the display element DE2 is formed in subpixel SP2. For example, this etching includes wet etching and dry etching processes which are performed in order for the sealing layer SE2, the cap layer CP2, the upper electrode UE2 and the organic layer OR2.

The margin area BA is also exposed to this etching. Thus, as shown in FIG. 16B, the stacked film FL2 and the sealing layer SE2 provided in the margin area BA and the surrounding area SA are removed. After this etching, the resist R2 is removed.

The display element DE3 is formed by a procedure similar to the procedures of the display elements DE1 and DE2. Specifically, to form the display element DE3, first, as shown in FIG. 17A and FIG. 17B, the stacked film FL3 and the sealing layer SE3 are formed in the entire mother substrate MB (process PR8). The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3. The organic layer OR3, the upper electrode UE3 and the cap layer CP3 are formed by vapor deposition. The sealing layer SE3 is formed by CVD.

The stacked film FL3 is divided into a plurality of portions by the partitions 6 and 7 having overhang shapes. The sealing layer SE3 continuously covers the divided portions of the stacked film FL3 and the partitions 6 and 7.

After process PR8, the stacked film FL3 and the sealing layer SE3 are patterned (process PR9). In this patterning, as shown in FIG. 17A, a resist R3 is provided on the sealing layer SE3. The resist R3 covers subpixel SP3 and part of the partition 6 around subpixel SP3. The resist R3 is not provided in the margin area BA or the surrounding area SA.

Subsequently, as shown in FIG. 18A, the portions of the stacked film FL3 and the sealing layer SE3 exposed from the resist R3 are removed by etching using the resist R3 as a mask. By this process, the display element DE3 is formed in subpixel SP3. For example, this etching includes wet etching and dry etching processes which are performed in order for the sealing layer SE3, the cap layer CP3, the upper electrode UE3 and the organic layer OR3.

The margin area BA and the surrounding area SA are also exposed to this etching. Thus, as shown in FIG. 18B, the stacked film FL3 and the sealing layer SE3 provided in the margin area BA and the surrounding area SA are removed. After this etching, the resist R3 is removed.

After the display elements DE1, DE2 and DE3 are formed, the resin layer 13, sealing layer 14 and resin layer 15 shown in FIG. 3 are formed in order for each panel portion PP (process PR10). Further, each panel portion PP is cut out from the mother substrate MB (process PR11). Each of the panel portions PP which have been cut out corresponds to the display panel PNL.

According to the display device DSP and mother substrate MB of the present embodiment, the yield at the time of manufacturing can be improved. This effect is explained below using FIG. 19 and FIG. 20.

FIG. 19 is a schematic cross-sectional view of the margin area BA (or the surrounding area SA) of a mother substrate MBc according to a comparative example. The mother substrate MBc is different from the mother substrate MB of the embodiment in respect that the mother substrate MBc does not comprise the partition 7, and the organic insulating layer 12 is covered with the inorganic insulating layer 100 in the margin area BA. The section of FIG. 19(a) corresponds to the same process as FIG. 13B. In the margin area BA, the stacked film FL1 and the sealing layer SE1 are formed.

In the patterning of the stacked film FL1 and the sealing layer SE1 (process PR5 of FIG. 7), the mother substrate MB is exposed to washing treatment such as water washing in the air and the development process of a resist. A tiny pinhole may be generated in the sealing layer SE1 formed of an inorganic insulating material. When moisture enters the stacked film FL1 through the pinhole in washing treatment, etc., and reaches the interface between the organic layer OR1 and the inorganic insulating layer 100, an exfoliation portion G in which the organic layer OR1 is raised from the surface of the inorganic insulating layer 100 could be generated.

If moisture interpenetrates the organic layer OR1, as shown in FIG. 19(b), the exfoliation portion G expands, and the adhesion between the stacked film FL1 and the inorganic insulating layer 100 is weakened. In this manner, as shown in FIG. 19(c), the stacked film FL1 and the sealing layer SE1 may be partly removed. The removed stacked film FL1 and sealing layer SE1 could cause the contamination of chambers, etc., in the manufacturing line. As the contaminated portion requires cleaning, the manufacturing line needs to be stopped.

FIG. 20 is a schematic cross-sectional view of the margin area BA (or the surrounding area SA) of the mother substrate MB of the embodiment. In FIG. 20(a), in the same manner as FIG. 19(a), the stacked film FL1 and the sealing layer SE1 are formed in the margin area BA. Further, moisture enters the stacked film FL1, and an exfoliation portion G is generated.

Moreover, in FIG. 20(b), the exfoliation portion G is expanded. However, in the embodiment, the partition 7 is provided in the margin area BA and the surrounding area SA, and the stacked film FL1 is divided by the partition 7. Thus, the expansion of the exfoliation portion G is prevented.

Specifically, when the exfoliation portion G is generated between the stacked film FL1 and the underlayer 11a as shown in FIG. 20, the expansion of this exfoliation portion G is limited to the inside of the closed area CA. When the exfoliation portion G is formed in the stacked film FL1 located on the partition 7, the expansion of this exfoliation portion G is limited to the area on the partition 7.

In the portion where the exfoliation portion G is generated as shown in FIG. 20(b), the stacked film FL1 is suppressed by the sealing layer SE1. Thus, the stacked film FL1 and the sealing layer SE1 are not easily removed.

When the partition 7 consists of the first linear portions 7x and the second linear portions 7y as shown in FIG. 5, each of the interval of adjacent first linear portions 7x (width Wx2 of each closed area CA) and the interval of adjacent second linear portions 7y (width Wy2 of each closed area CA) should be preferably less than or equal to 200 μm. By this configuration, the width of the exfoliation portion G in the closed area CA can be suppressed in a narrow range less than or equal to 200 μm, and thus, the stacked film FL1 or the sealing layer SE1 does not easily result in removal.

Although this specification particularly looks at the stacked film FL1 and the sealing layer SE1 in FIG. 19 and FIG. 20, similar exfoliation could be generated in the stacked films FL2 and FL3 and the sealing layers SE2 and SE3. The embodiment can also prevent the exfoliation of these stacked films FL2 and FL3 and sealing layers SE2 and SE3.

The display device DSP, the mother substrate MB or the manufacturing method thereof is not limited to the disclosure of the embodiment. For example, other than the disclosure of the embodiment, various configurations can be applied to the margin area BA and the surrounding area SA as exemplarily shown in the second to fourth embodiments described below.

### Second Embodiment

FIG. 21 is a schematic cross-sectional view of a margin area BA (or a surrounding area SA) according to a second embodiment. In the example of this figure, a bottom portion 73 is formed on an underlayer 11a in a closed area CA. The bottom portion 73 is formed of the same organic insulating material as a lower portion 71 and is connected to the lower portion 71.

Both the lower portion 71 and the bottom portion 73 are formed by processing an organic insulating layer 12. Specifically, the bottom portion 73 can be formed by leaving part of the organic insulating layer 12 in the closed area CA in the ashing shown in FIG. 12B(b).

### Third Embodiment

FIG. 22 is a schematic cross-sectional view of a margin area BA (or a surrounding area SA) according to a third embodiment. In the example of this figure, an upper portion 72 is formed of the same conductive material as lower electrodes LE1, LE2 and LE3. When each of the lower electrodes LE1, LE2 and LE3 comprises a pair of conductive oxide layers and a reflective layer between the conductive oxide layers as described above, the upper portion 72 includes three layers which correspond to these conductive oxide layers and reflective layer, respectively.

Each of FIG. 23 to FIG. 26 is a schematic cross-sectional view showing a process for forming a partition 7 according to the embodiment. To manufacture the display device DSP of the embodiment, in place of the processes shown in FIG. 9B to FIG. 12B, the processes shown in these FIG. 23 to FIG. 26 are performed.

Specifically, when the lower electrodes LE1, LE2 and LE3 are formed (see FIG. 9A), as shown in FIG. 23, a conductive layer CD is patterned into the shape of the upper portion 72 in the margin area BA and the surrounding area SA.

Subsequently, as shown in FIG. 24, in a manner similar to that of the process of FIG. 10B, an inorganic insulating layer 100, a first layer 101 and a second layer 102 are formed. All of these inorganic insulating layer 100, first layer 101 and second layer 102 are removed in the margin area BA and the surrounding area SA as shown in FIG. 25.

Subsequently, ashing is performed for an organic insulating layer 12 in a manner similar to that of the process of FIG. 12B(b). By this process, a lower portion 71 is formed as shown in FIG. 26.

Even when the upper portion 72 is formed of the same conductive material as the lower electrodes LE1, LE2 and LE3 like the embodiment, effects similar to those of the first embodiment can be obtained.

### Fourth Embodiment

FIG. 27 is a schematic cross-sectional view of a margin area BA (or a surrounding area SA) according to a fourth embodiment. In the example of this figure, in the same manner as the second embodiment, a bottom portion 73 is formed in a closed area CA. Further, in the same manner as the third embodiment, an upper portion 72 is formed by patterning a conductive layer CD.

Other than the embodiments described above, various configurations could be applied to the partition 7. For example, the upper portion 72 may include a layer formed of an inorganic insulating material as in the case of the first and second embodiments, and a layer formed of a conductive material as in the case of the third and fourth embodiments.

Further, the planar shape of the partition 7 is not limited to that of FIG. 5. For example, the partition 7 may not necessarily form the closed areas CA. As another example, the partition 7 may consist of a plurality of linear portions provided parallel to each other, and these linear portions may be connected to each other. Even this configuration suppresses the expansion of the exfoliation portion G in the arrangement direction of the linear portions.

Further, the partition 7 provided in the margin area BA and the partition 7 provided in the surrounding area SA may have different shapes. As yet another example, the partition 7 may not be provided in the surrounding area SA.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A mother substrate for a display device, comprising:
a plurality of panel portions each of which includes a display area in which a plurality of display elements are provided;
a margin area around the panel portions; and
a first partition provided in the margin area, wherein
each of the display elements includes a lower electrode, an upper electrode which faces the lower electrode, and an organic layer which is provided between the lower electrode and the upper electrode and emits light based on a potential difference between the lower electrode and the upper electrode, and
the first partition includes a first lower portion formed of an organic insulating material, and a first upper portion comprising an end portion which protrudes from a side surface of the lower portion.

2. The mother substrate of claim 1, wherein
the panel portion comprises an organic insulating layer formed of the same organic insulating material as the first lower portion and provided in the display area, and
the lower electrode is provided above the organic insulating layer.

3. The mother substrate of claim 1, wherein
the panel portion comprises a rib comprising a pixel aperture overlapping the lower electrode,
the organic layer is in contact with the lower electrode through the pixel aperture, and
the rib and the first upper portion are formed of a same inorganic insulating material.

4. The mother substrate of claim 1, wherein
the lower electrode and the first upper portion are formed of a same conductive material.

5. The mother substrate of claim 1, wherein
each of the panel portions further comprises a surrounding area around the display area, and
the first partition is provided in the margin area and the surrounding area.

6. The mother substrate of claim 1, wherein
the first partition comprises a plurality of linear portions provided parallel to each other, and
the linear portions are arranged at intervals less than or equal to 200 μm.

7. The mother substrate of claim 1, wherein
the first partition forms a plurality of closed areas as seen in plan view.

8. The mother substrate of claim 1, wherein
each of the panel portion comprises a second partition provided between the display elements in the display area, and
the second partition includes a second lower portion, and a second upper portion comprising an end portion which protrudes from a side surface of the second lower portion.

9. The mother substrate of claim 1, further comprising:
an insulating layer located under the first partition in the margin area;
a stacked film which includes the organic layer and the upper electrode and covers the insulating layer and the first partition; and
a sealing layer which covers the stacked film, wherein
the stacked film is divided into a plurality of portions by the first partition, and
the sealing layer continuously covers the plurality of portions.

10. A display device comprising:
a display area in which a plurality of display elements are provided;
a surrounding area around the display area; and
a first partition provided in the surrounding area, wherein
each of the display elements includes a lower electrode, an upper electrode which faces the lower electrode, and an organic layer which is provided between the lower electrode and the upper electrode and emits light based on a potential difference between the lower electrode and the upper electrode, and
the first partition includes a first lower portion formed of an organic insulating material and a first upper portion comprising an end portion which protrudes from a side surface of the first lower portion.

11. The display device of claim 10, further comprising an organic insulating layer formed of the same organic insulating material as the first lower portion and provided in the display area, wherein
the lower electrode is provided above the organic insulating layer.

12. The display device of claim 10, further comprising a rib comprising a pixel aperture overlapping the lower electrode, wherein
the organic layer is in contact with the lower electrode through the pixel aperture, and
the rib and the first upper portion are formed of a same inorganic insulating material.

13. The display device of claim 10, wherein
the lower electrode and the first upper portion are formed of a same conductive material.

14. The display device of claim 10, further comprising a second partition provided between the display elements in the display area, wherein
the second partition includes a second lower portion, and a second upper portion comprising an end portion which protrudes from a side surface of the second lower portion.

15. A manufacturing method of a display device, including:
preparing a substrate including a plurality of panel portions each of which includes a display area, and a margin area around the panel portions;
forming an organic insulating layer formed of an organic insulating material in the display area and the margin area;
forming a conductive layer formed of a conductive material which covers the organic insulating layer in the display area and the margin area;
forming a lower electrode of a display element by patterning the conductive layer in the display area;
forming an inorganic insulating layer formed of an inorganic insulating material which covers the lower electrode in the display area and the margin area;
forming a rib comprising a pixel aperture overlapping the lower electrode by patterning the inorganic insulating layer in the display area; and
forming a first partition including a first lower portion and a first upper portion comprising an end portion which protrudes from a side surface of the first lower portion in the margin area, wherein
the forming the first partition includes:
forming the first upper portion by patterning the conductive layer or the inorganic insulating layer in the margin area; and
forming the first lower portion by removing a portion of the organic insulating layer exposed from the first upper portion and reducing a width of the organic insulating layer which remains under the first upper portion in the margin area.

16. The manufacturing method of claim 15, wherein
the forming the first upper portion includes:
removing the conductive layer in the margin area before forming the inorganic insulating layer; and
patterning the inorganic insulating layer into a shape of the first upper portion after forming the inorganic insulating layer.

17. The manufacturing method of claim 15, wherein
the forming the first upper portion includes:
patterning the conductive layer in the margin area into a shape of the first upper portion before forming the inorganic insulating layer; and
removing the inorganic insulating layer in the margin area after forming the inorganic insulating layer.

18. The manufacturing method of claim 15, further including
forming a second partition including a second lower portion and a second upper portion comprising an end portion which protrudes from a side surface of the second lower portion in the display area.

19. The manufacturing method of claim 18, further including:
forming a stacked film including an organic layer which is in contact with the lower electrode through the pixel aperture and an upper electrode which covers the organic layer in the display area and the margin area; and
forming a sealing layer which covers the stacked film and is formed of an inorganic insulating material in the display area and the margin area, wherein
the stacked film is divided into a plurality of portions by the first partition and the second partition, and
the sealing layer continuously covers the plurality of portions.

20. The manufacturing method of claim 19, further including
forming a display element including the lower electrode, the organic layer and the upper electrode in the display area by patterning the stacked film and the sealing layer, and removing the stacked film and the sealing layer in the margin area.
